(19) United States
(12) Patent Application Publication
(10) Pub. No.: US 2018/0358257 A1
(43) Pub. Date: Dec. 13, 2018

(54) IC WITH TRENCHES FILLED WITH ESSENTIALLY CRACK-FREE DIELECTRIC

(71) Applicant: Texas Instruments Incorporated, Dallas, TX (US)

(72) Inventors: TAKAYUKI ENDA, FUKUSHIMA (JP); JUN IGARASHI, FUKUSHIMA (JP); TAKAAKI IWASAWA, FUKUSHIMA (JP); ASAD MAHMOOD HAIDER, PLANO, TX (US); HIROYUKI SASAKI, FUKUSHIMA (JP)

(21) Appl. No.: 15/618,586

(22) Filed: Jun. 9, 2017

(51) Int. Cl. H01L 21/74; H01L 27/12; H01L 29/06; H01L 29/78; H01L 29/10; H01L 21/84

(52) U.S. Cl. CPC H01L 21/743; H01L 27/1203; H01L 21/84; H01L 29/7816; H01L 29/1087; H01L 29/0649

(57) ABSTRACT

A method of forming an integrated circuit includes forming at least one hard mask layer on a device layer of a silicon-on-Insulator (SOI) substrate. A patterned trench etch forms larger area and smaller area trenches through the hard mask layer, device layer and BOX layer. A dielectric liner is formed for lining the larger area and smaller area trenches. A sub-atmospheric pressure chemical vapor (SACVD) dielectric layer is deposited for filing the smaller area trenches and partially filling the larger area trenches. The larger area trenches are bottom etched through the SACVD layer to provide a through-substrate contact (TSC) to the handle portion. The SACVD layer is densified after bottom etching, the handle portion at a bottom of the larger area trenches is implanted to form a handle contact, and the larger area trenches are filled with an electrically conductive layer to form a top side ohmic contact.

### FIELD

Disclosed embodiments relate to semiconductor device fabrication and more specifically to sub-atmospheric pressure chemical vapor deposition (SACVD) for trench filling during fabrication of semiconductor devices and integrated circuits therefrom.

### BACKGROUND

Silicon-on-Insulator (SOI) is a semiconductor technology that produces higher performing, lower power (dynamic) devices as compared to traditional bulk silicon-based technology. SOI substrates are used for a variety of applications including Micro-Electro-Mechanical Systems (MEMS), power devices, and complementary metal-oxide-semiconductor (CMOS) integrated circuits (ICs). The SOI wafer comprises a sandwich structure including a device layer (or active layer) on the top, a buried oxide (BOX) layer (dielectric typically being silicon oxide) in the middle, and a handle portion or ‘handle wafer’ (typically being bulk silicon) on the bottom. SOI wafers can be produced by using a SIMOX (Separation by IMplantation of Oxygen) process which uses a very high dose oxygen implant process followed by a high temperature anneal, or wafer bonding to achieve thinner and precise device layer and ensure the requirement of thickness uniformity and low defect density.

SOI technology may include dielectric filled isolation trenches that reach the BOX layer and also a polysilicon filled top side contact (TSC) trench, also sometimes called a trench-substrate-contact, to provide a low resistance Ohmic contact to the handle portion when a top side to the handle portion contact is needed on the IC to avoid the need for a down bond. One process flow employs forms in separate steps both an isolation trench and a TSC trench that are both through the BOX layer. The TSC trench can receive doping of the surface contact in the handle portion of the TSC trench, followed by forming doped polysilicon in the TSC trench to provide an IC top side electrically conductive handle portion contact.

Conventional chemical vapor deposition (CVD) may no longer provide the needed step coverage for completely filling high aspect ratio trenches, which are commonly used on advanced ICs. SACVD operates at a pressure range from 10 s of Torrs to <760 Torr (760 torr =normal atmospheric pressure), typically at about 400 to 700 Torr, much higher than low pressure CVD (LPCVD) which operates at a pressure generally from 0.01 to 10 Torr. Ozone (O₃)-assisted SACVD deposition techniques are known to provide a high deposition rate, and excellent uniformity as well as good step coverage to enable superior gap filling ability that is desirable for high aspect ratio trenches. After the SACVD film deposition, a high-temperature anneal is performed generally in nitrogen to densify the as-deposited SACVD film. Typically, the densifying process is generally conducted at a temperature in the 600° C. to 1000° C. range which in the case of a tetraethyl orthosilicate (TEOS)-based SACVD oxide deposition drives out moisture and siloxyl groups, and densifies the oxide layer making it tensile. A TSC trench bottom etch follows the densification.

However, SACVD film cracking can be a problem particularly for thick SACVD oxide layers (e.g., >8 kA). A known method of controlling SACVD layer cracking is to deposit a dense SACVD oxide layer by manipulating process parameters such as the TEOS to O₃ reactant flow ratio. Another technique for controlling SACVD layer cracking is to perform a multi-pass deposition, for example using a first deposition to deposit 5 kA of SACVD oxide and a second deposition to deposit another 5 kA of SACVD oxide, with an in-situ deposition chamber clean used in between the respective depositions. Yet another known technique is to do a multi-pass deposition with an intermediate SACVD oxide densification step.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed embodiments include a method of forming an IC comprising forming at least one hard mask layer on a device layer of a SOI substrate that includes the device layer on a top, BOX layer in a middle, and a handle portion on a bottom. A pattern is etched to form larger area trenches and smaller area trenches through the hard mask layer, device layer and BOX layer. A dielectric liner is formed for lining the larger area trenches and lining the smaller area trenches. An SACVD dielectric layer is deposited for filling the smaller area trenches and partially filling the larger area trenches.

The larger area trenches are bottom etched through the SACVD dielectric layer to provide a top side contact to the handle portion. The SACVD dielectric layer is densified after the bottom etching, the handle portion implanted at a bottom of the larger area trenches to form a handle contact, and the larger area trenches are filled with an electrically conductive layer to form a top side ohmic contact to the handle contact.

Disclosed ICs have at least one unique feature resulting from disclosed SACVD dielectric layer densification after the trench etch step for etching the TSC and isolation trenches being the SACVD dielectric layer in the TSC trenches and isolation trenches being essentially crack-free. As used herein the term “crack” in a disclosed “crack-free” SACVD dielectric layer refers to the absence of visible lines under scanning electron microscope (SEM) inspection which evidence cracks and the absence of irregularities which evidence volume cracks that can be considered voids.

SACVD dielectric layer cracks are determinable from a top down inspection of the wafer under an optical microscope or a SEM image at magnifications that reveal features of 250 A or less. For example, the KLA 2139 Brightfield defect inspection system (from KLA-Tencor, Milpitas, Calif.) can be programmed to automatically identify cracks in the SACVD dielectric layer. The term “essentially void-free” applied to an IC as used herein refers to the deposited dielectric layer on the thermal dielectric liner in the isolation trenches being interface-free (resulting from a single SACVD dielectric deposition), having a depth of >5 μm an AR >3, are at least 4 kA in width, and wherein at least 90% of the isolation trenches are crack-free throughout their volume.

Moreover, disclosed isolation trenches have a deposited dielectric layer that is interface-free resulting from only a single dielectric deposition so that there will be only single dielectric liner/deposited dielectric interface. This dielectric liner/deposited dielectric single interface is however generally very difficult to tell apart even under a transmission electron microscope (TEM). As known in the art, a silicon oxide layer deposited through a CVD process including in the final IC (even after their typical densification during ordinary processing) is structurally distinguishable from a thermally grown silicon oxide layer as evidenced by its lower dielectric strength and index of refraction as compared to the thermally grown silicon oxide layer. For example, an index of refraction for a thermal oxide is generally about 1.46, while an index of refraction for a deposited SACVD oxide (without polysilicon therein) is generally no higher than 1.45. Other differences include a difference in intrinsic film stress and also a difference in etch rates with a hydrofluoric acid (HF) etchant, for example.

Thus, a known 2-deposition dielectric layer trench filling process that may include a dielectric densification between the respective depositions that follows forming a thermal liner in the trenches results in both a thermal dielectric/deposited dielectric interface and a first deposited dielectric/second deposited dielectric interface, even if the deposited dielectric material is set in the deposition recipe to be the same in the first and second deposition. Disclosed isolation trenches having a deposited dielectric layer that is interface-free resulting from using only a single dielectric deposition are thus structurally distinct from the structure resulting from using a known 2-deposition dielectric layer trench filling process.

The AR of the isolation trenches is generally from 3 to 15. Disclosed crack-free SACVD dielectric helps with maintaining a high breakdown voltage across the isolation trenches on the IC, such as >200V.

### BRIEF DESCRIPTION OF THE DRAWINGS

Reference will now be made to the accompanying drawings, which are not necessarily drawn to scale, wherein:

FIGS. 1A-1J are schematic cross-sectional diagrams showing process progression for an example method of forming trenches filled with an essentially crack-free SACVD dielectric material, according to an example embodiment.

FIG. 2 is a cross sectional view of a portion of an IC having transistors in the device areas that are isolated from one another by disclosed isolation trenches including TSC trenches for top side handle portion contact, according to an example embodiment.

FIG. 3A shows top-down images for SACVD oxide crack data showing results from known trench filling with a TSC bottom etch after SACVD oxide densification and FIG. 3B shows crack data results from using disclosed trench filling having the TSC bottom etch before the SACVD oxide densification evidencing essentially crack-free SACVD oxide.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Also, the terms “coupled to” or “couples with” (and the like) as used herein without further qualification are intended to describe either an indirect or direct electrical connection. Thus, if a first device “couples” to a second device, that connection can be through a direct electrical connection where there are only parasitics in the pathway, or through an indirect electrical connection via intervening items including other devices and connections. For indirect coupling, the intervening item generally does not modify the information of a signal but may adjust its current level, voltage level, and/or power level.

Disclosed embodiments include an SOI-based IC process flow that uses a single mask level to form both high aspect ratio (AR) isolation trenches (e.g., 3 to 15), and lower AR TSC trenches that ohmically contact the handle portion of the SOI die from the top side so that the IC can be biased at a desired voltage without the need for a down bond. Typical trench depths may range from 5 μm to 15 μm, and the isolation trench widths may range from 0.6 μm (6 kA) to 1.6 μm. It has been found that the SACVD silicon oxide layer used to fill these high AR isolation trenches cracks post-SACVD deposition when followed by high temperature steps including SACVD oxide densification.

Disclosed embodiments recognize known methods for controlling SACVD oxide layer cracking by manipulating the TEOS to O₃ gas ratio as well as multi-pass depositions both still result in significant SACVD oxide layer cracking when the deposited SACVD layer thickness is at least 5 kA which is generally needed to completely fill the high AR trenches. This is because there is a critical SACVD dielectric layer thickness beyond which the SACVD dielectric layer cracks depending upon the mechanical properties of the SACVD oxide layer, such as its intrinsic stress, and Young's modulus. For example, it has been found that depositing 10 kA of SACVD oxide cracks upon a 950° C. densification.

Disclosed processing changes the trench processing by moving the SACVD dielectric layer densification step to occur after the trench dielectric etch step for etching the TSC trenches and isolation trenches. By performing the TSC etch before this densification thins down this as-deposited SACVD dielectric layer in the case of 10 kA of SACVD as-deposited to about 5 kA (about 1/2 (50%) of the as-deposited thickness). The thinned SACVD dielectric layer thickness being below the critical SACVD dielectric layer thickness is believed to enable the SACVD dielectric layer to not crack upon densification and subsequent IC processing despite becoming more brittle after densification.

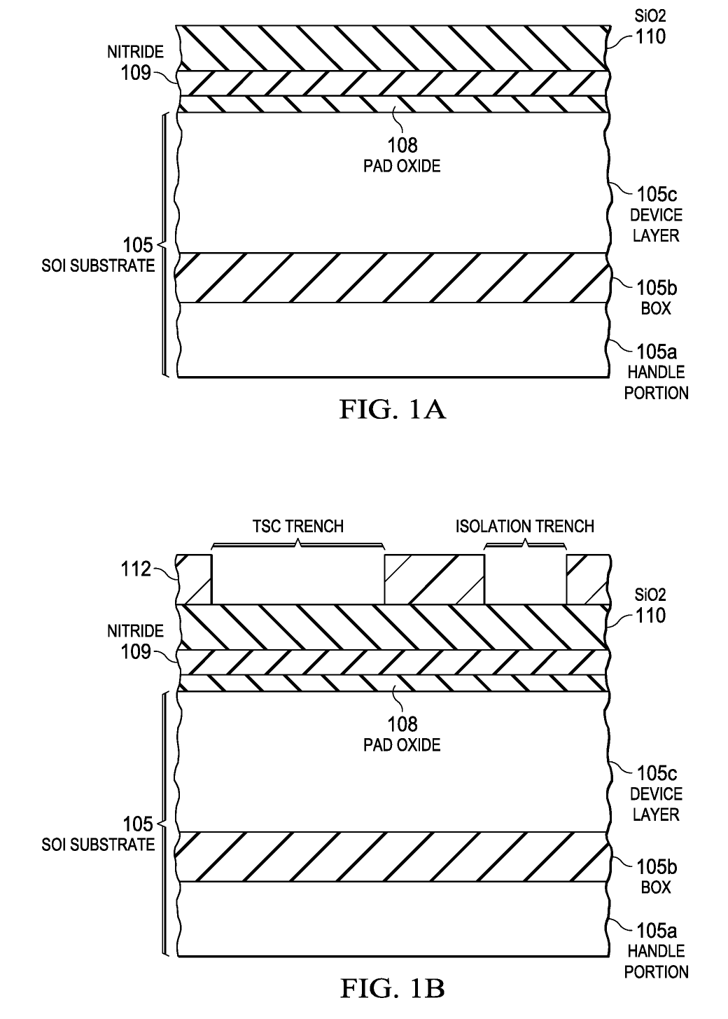

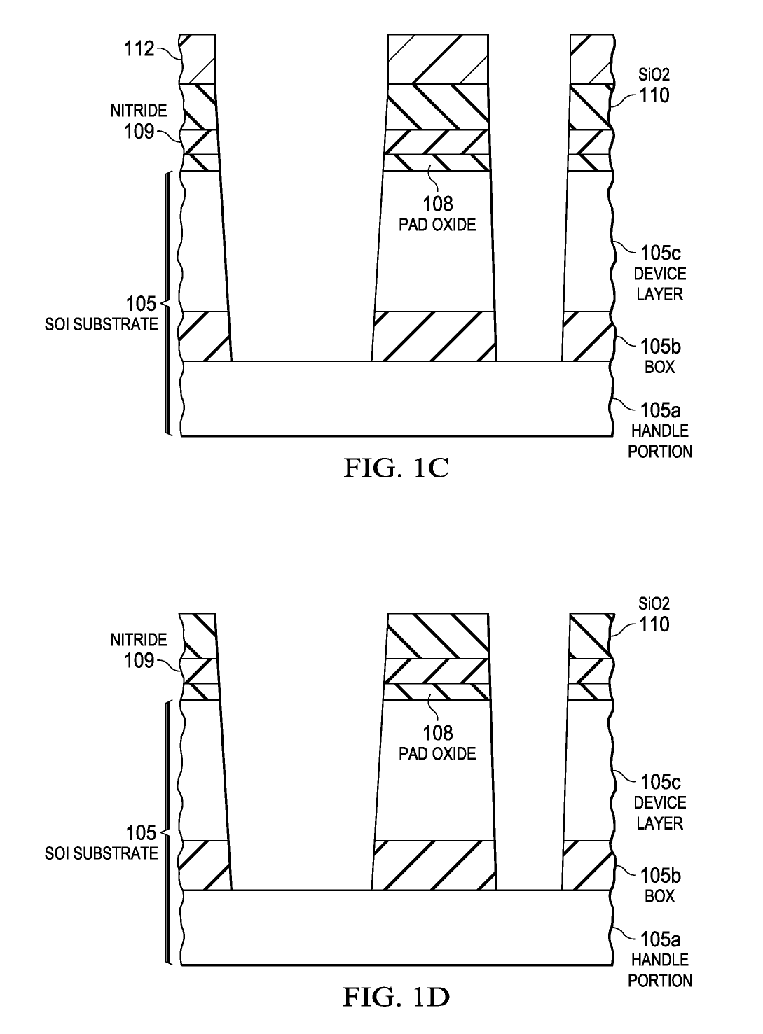

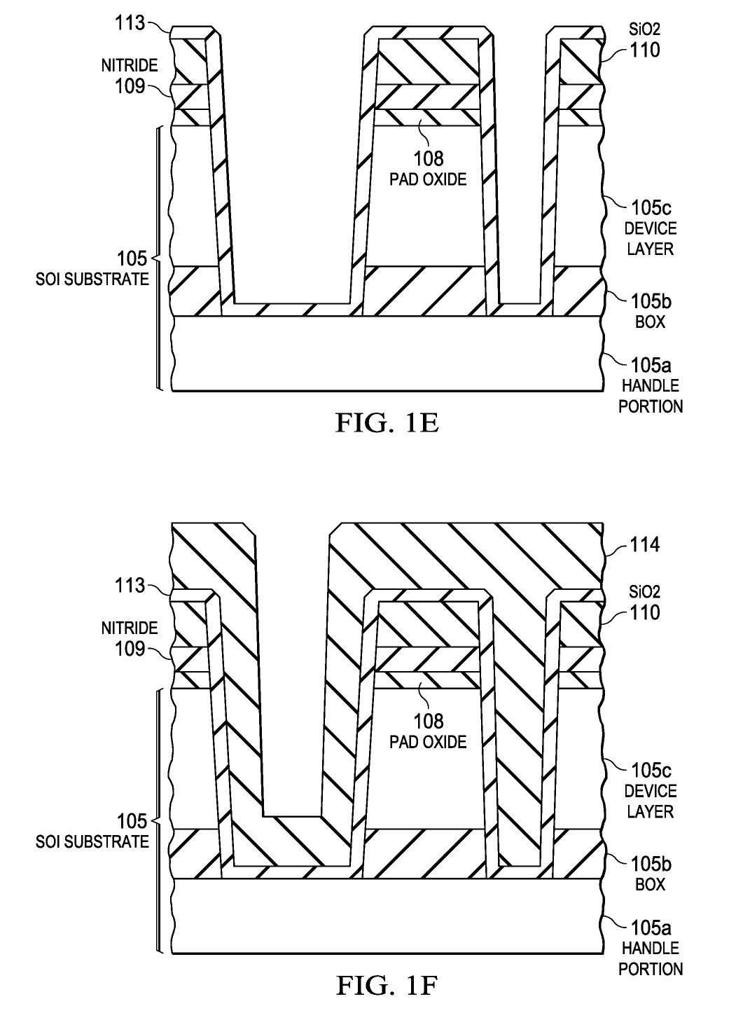

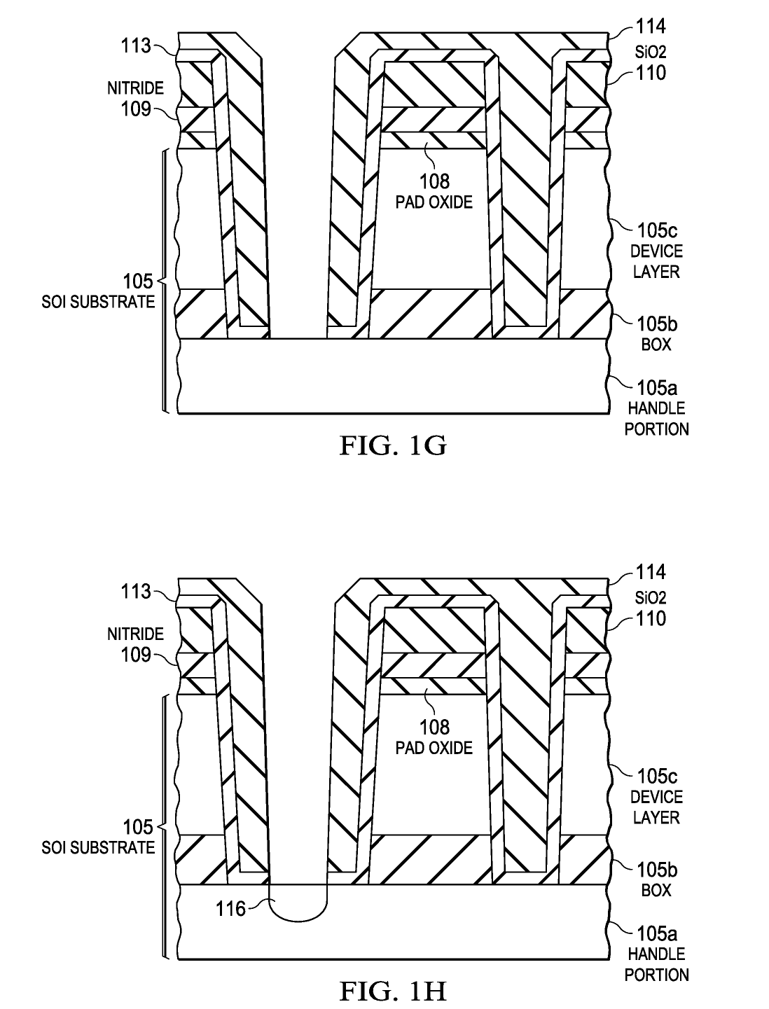

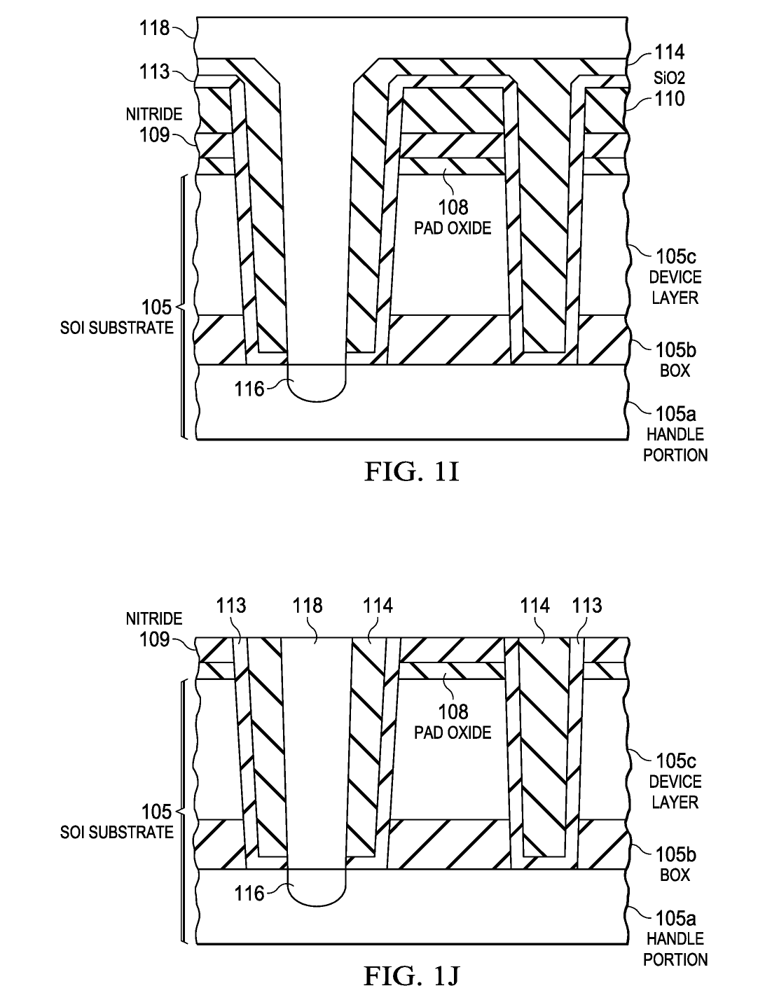

FIGS. 1A-1J are schematic cross-sectional diagrams showing process progression for an example method of forming an IC with trenches filled with an essentially crack-free SACVD dielectric material. This method described by FIGS. 1A-1J uses a single mask level to form both high AR isolation trenches and lower AR TSC trenches. However, disclosed trench filling with essentially crack-free dielectric can also be applied to processes that use separate masking levels for forming the high AR isolation trenches and lower AR TSC trenches.

FIG. 1A shows a portion of the in-process IC after the depositing of at least one hard mask layer on a device layer 105c (or ‘active layer’) of a SOI substrate 105. The SOI substrate 105 includes the device layer 105c on the top, a BOX layer 105b in the middle, and a handle portion 105a on the bottom. The hard mask layer is shown by example as a three-layer hard mask stack including a top deposited silicon oxide layer 110, a deposited silicon nitride layer 109 in the middle, and thermal silicon ‘pad’ oxide layer 108 on the bottom.

In a typical embodiment the device layer 105c comprises silicon, the BOX layer 105b comprises silicon oxide, and the handle portion 105a comprises silicon. The device layer 105c can comprise a lower portion comprising single crystal silicon from the SOI substrate from an SOI wafer vendor and an upper portion comprising an epitaxial silicon layer. The device layer 105c can be from 3 μm to 6 μm thick, the BOX layer 105b can be from 1 μm to 3 μm thick, and the handle portion 105a can be from 500 μm to 1,000 μm thick. In one embodiment the top deposited silicon oxide layer 110 is PECVD deposited and is 1 μm to 1.5 μm thick, the deposited silicon nitride layer 109 is LPVCD deposited and is 1.5 μm to 3 μm thick, and the thermal silicon oxide layer 108 on the bottom is 100 A to 300 A thick and is thermally grown.

FIG. 1B shows a portion of the in-process IC after forming a pattern to define larger area trenches shown as over an area that will be a TSC trench which will contact a top surface of the handle portion 105a as well as smaller area trenches shown as an isolation trench which extend into the BOX layer 105b. The forming of the pattern can comprise photoresist coating, patterning and developing to provide the patterned mask layer 112 shown.

FIG. 1C shows a portion of the in-process IC after deep trench etching to simultaneously form both trenches for the larger area TSC trenches and the smaller area isolation trenches. The trench etching can comprise deep reactive ion etching (DRIE) which anisotropically etches through the hard mask layers 110, 109, 108, the device layer 105c and BOX layer 105b to enable biasing the handle portion 105a from the top side of the IC during operation of the IC. As noted above the trench depth can range from 5 μm to 15 μm, and the trench widths for the isolation trenches can be 0.6 μm to 1.6 μm. The trench width for the TSC trenches can be 1.5× or larger than the isolation trench width, such as from 1.5× to 4× of the isolation trench width. FIG. 1D shows a portion of the in-process IC after removal of the mask layer 112. For example, the removal can comprise ashing and then cleaning in the case mask layer 112 comprise photoresist.

FIG. 1E shows a portion of the in-process IC after forming a dielectric liner 113 for lining the larger area TSC trenches and lining the smaller area isolation trenches. The dielectric liner 113 can comprise a deposited High Temperature Oxide (HTO) liner using a LPCVD process at temperature of 500° C. or higher, or a thermally grown oxide. The dielectric liner 113 is generally 100 A to 300 A thick.

FIG. 1F shows a portion of the in-process IC after depositing a SACVD dielectric layer 114 shown partially filling the larger area TSC trenches and completely filling the smaller area isolation trenches. The SACVD dielectric layer 114 can comprise silicon oxide or silicon oxynitride. The SACVD dielectric layer can also comprise other dielectric materials that provide a high breakdown voltage barrier for the isolation trench, be low stress so it does not have a tendency to crack, have low shrinkage when thermally cycled, provide good fill capability, and generally be relatively low cost.

A typical deposition pressure used for the SACVD deposition is from 300 torr to 700 torr. For depositing silicon oxide the reagents can comprise TEOS and O₃ in a temperature range from 500° C. to 560° C., with the deposited thickness range depending on the trench volume for the smaller area isolation trenches being filled, such as 0.9 μm to 1.1 μm thick in one embodiment. SACVD is capable of completely filling high AR trenches, such as isolation trenches having an AR of from 3 to 15.

FIG. 1G shows a portion of the in-process IC after bottom etching of the larger area TSC trenches through the SACVD dielectric layer 114 to provide a TSC opening extending to the handle portion 105a. As noted above, unlike known TSC processing which densifies the SACVD dielectric layer 114 and then performs the TSC bottom etch on a densified SACVD dielectric layer 114, disclosed TSC processing perform the TSC bottom etch on the as-deposited (undensified) SACVD dielectric layer 114, and then densifies the etched SACVD dielectric layer 114 (removing the voids therein).

There is generally no masking layer used for this bottom etching so that the SACVD dielectric layer 114 is blanket etched resulting in the field regions of the SACVD dielectric layer 114 being thinned too as shown in FIG. 1G. The blanket etch process can comprise a plasma etch process using C₄F₈/Ar/O₂ chemistry at about 40 mTorr and 1,700 W of radio frequency (RF) power. For disclosed methods the thickness of the SACVD dielectric layer 114 decreases during both this bottom etching process as well as the subsequent thermal densification step, and more of a thickness decrease generally results from the bottom etching in the case of a plasma etch compared to the thermal densification.

The SACVD dielectric layer 114 densifying after the bottom etching can comprise furnace annealing at around 950° C. to 1050° C. for 20 to 40 minutes in a non-oxidizing ambient such as a N₂ ambient. The SACVD densification in the case of a TEOS-based SACVD oxide drives away moisture and siloxol (Si—OH) groups not removed in the bottom etching which results in further film shrinkage, and with a higher density and becoming more tensile which makes the SACVD layer more susceptible to cracking especially with higher thickness. However, as noted above, disclosed TSC processing by performing the TSC bottom etch on the as-deposited (undensified) SACVD dielectric layer 114, and then densifying the etched SACVD dielectric layer 114 avoids SACVD oxide layer cracking.

The SACVD dielectric layer 114 thickness range after densifying and blanket bottom etching for an as-deposited SACVD dielectric layer 114 thickness of 0.9 μm to 1.1 μm is less than 0.45 μm (=4.5 kA) on the field, thus providing more than a 50% total thickness reduction. The densification process generally results in 4% to 10% film shrinkage while the bulk of the thickness decrease generally results from the earlier bottom etch process.

FIG. 1H shows a portion of the in-process IC after ion implanting bottom of the larger area trenches TSC trenches (TSC bottom implanting) including implanting into the handle portion 105a to form a handle portion contact 116. For example, boron may be used with a dose from 1×10¹⁴ to 9×10¹⁵cm⁻², an energy from 20 keV to 40 keV, a 0 degree tilt and a 45 degree twist angle. This ion implant is generally a blanket implant. Boron is thus implanted into the entire surface of SACVD layer but later in the process the SACVD layer on the field regions is removed during CMP.

FIG. 1I shows a portion of the in-process IC after filling the TSC trenches with a an electrically conductive layer 118 referred to as being a doped polysilicon layer to form a top side ohmic contact to the handle portion contact 116 with the doped polysilicon layer shown extending lateral to the TSC trench as overburden portions. An in-situ doped polysilicon deposition can comprise LPCVD utilizing silane (SiH₄) gas and a dopant gas such as BCl₃ (for a p-type handle contact) at a deposition temperature range of 550° C. to 650° C. and a pressure range from 100 mTorr to 400 mTorr. The doped polysilicon thickness may be about 1.6 μm to 2.2 μm. In-situ doped polysilicon may be used, or it can be deposited undoped then ion implanted to dope it. However, in-situ doped polysilicon may be preferred in processes where there is insufficient thermal cycling for the implanted dopants to reach deep enough into the polysilicon filled TSC which would otherwise result in high TSC resistance. After completion of fabricating the IC the polysilicon filled TSC generally has a 25° C. sheet resistance less than or equal (≤) 70 ohms/sq.

FIG. 1J shows a portion of the in-process IC after removing the overburden portions of the electrically conductive layer 118 (e.g., doped polysilicon layer). Chemical Mechanical Planarization (CMP) may be used. The poly CMP process is shown stopping on the silicon nitride layer 109. Although not shown, as well known in the art subsequent IC processing includes lithography, etching, thin film depositions and growth, diffusion, and ion implants for forming a desired pattern of transistors, resistors and capacitors, and then metallization generally comprising a multi-level metallization stack, followed by a patterned passivation layer.

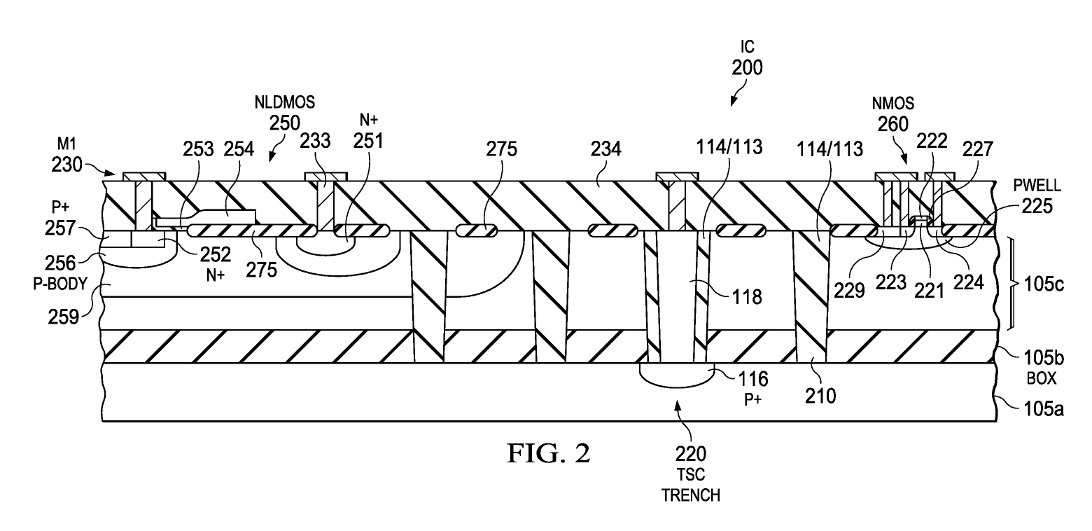

FIG. 2 is a cross sectional view of a portion of an IC 200 having transistors in the device areas that are isolated from one another by disclosed isolation trenches now shown as 210 along with TSC trenches shown as 220 for top side handle portion contact. Because characteristics of many different kinds of circuit components are affected by handle portion bias, the TSC trenches 220 on IC 200 provide the desirable ability to control the handle voltage bias at an appropriate bias level from the top side of the IC without the conventional need for down bonds to either ground the handle portion or maintain the handle portion at a desired voltage.

For simplicity the metal stack is shown as only a patterned metal 1 (M1) layer 230 connecting through filled (e.g., tungsten (W) filled) vias 233 that are through a pre-metal dielectric layer 234 to provide contact to features in or on the top surface of the device layer 105c. Not all needed contacts are shown, such as contacts to the respective gates. Typically, the metal stack will include 4 or more metal layers with an interlevel dielectric (ILD) layer having vias therein between the respective metal layers.

The transistors shown comprise a laterally diffused n-channel metal-oxide-semiconductor (NLDMOS) transistor 250, and a conventional n-channel MOS (NMOS) transistor 260. The field oxide is shown as a Local Oxidation of Silicon (LOCOS) oxide 275, but can also comprise shallow trench isolation (STI). As used herein, an LDMOS device is synonymous with a diffused metal oxide semiconductor (DMOS) device or drain extended MOS (DEMOS), and can include both n-channel LDMOS (NLDMOS) and p-channel PLDMOS devices. In NLDMOS transistor 250, the drain 251 is laterally arranged to allow current to laterally flow, and an n- drift region is interposed between the channel and the drain to provide a high drain 251 to source 252 breakdown voltage (BV). The source 252 is in a p-body region 256 (sometimes called a DWELL region) formed within an n-body region 259 that has a p+ contact 257. LDMOS devices are thus generally designed to achieve higher BV while minimizing specific ON-resistance in order to reduce conduction power losses. NLDMOS transistor 250 also has a gate electrode 254 such as an n+ polysilicon gate that is on a gate dielectric layer 253.

NMOS transistor 260 includes a gate electrode 221 on a gate dielectric 222 along with a drain 223 and source 224 formed in a pwell 225. Spacers 227 are shown on the sidewalls of the gate stack of the NMOS transistor 260. There is also a p+ contact 229 shown to the pwell 225. The IC 200 can also include PMOS devices by generally changing the doping types relative to NMOS devices.

### EXAMPLES

Disclosed embodiments of the invention are further illustrated by the following specific Examples, which should not be construed as limiting the scope or content of this Disclosure in any way.

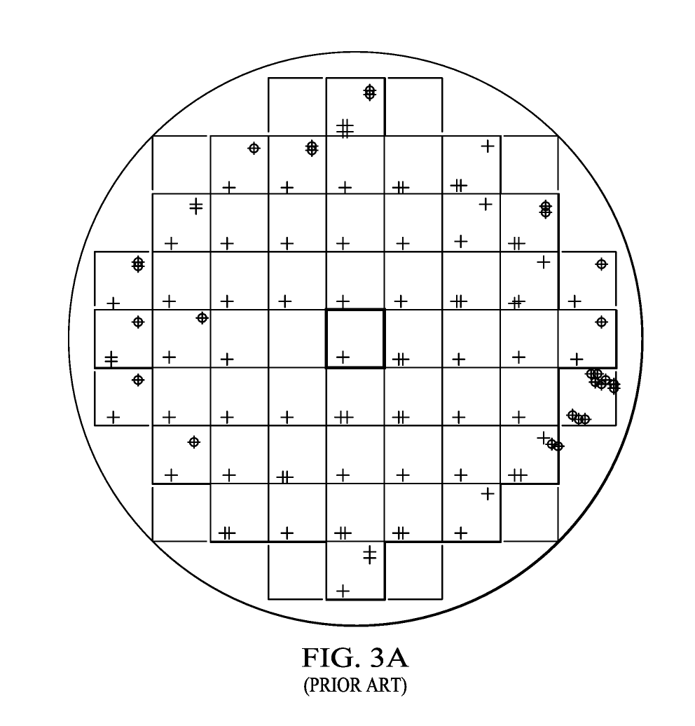

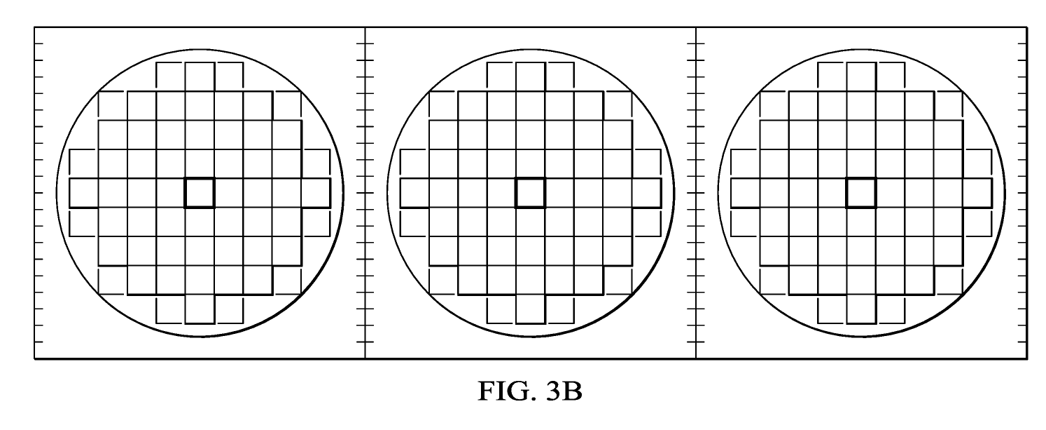

FIG. 3A shows top-down images for SACVD oxide crack data showing results from known trench filling and FIG. 3B results from a TSC bottom etch after SACVD oxide densification with disclosed trench filling having the TSC bottom etch before SACVD oxide densification evidencing essentially crack-free SACVD oxide. The SOI wafers had a trench width of 1 μm and trench depth 7.5 μm, a 10 kA thick SACVD oxide film as-deposited using a densification at 1000° C. for 30 min were formed using known trench filling as a control for disclosed trench filling having the trench bottom etch before SACVD oxide densification.

The die size was 175 μm×175 μm. These wafers were inspected using an automated KLA 2139 Brightfield defect inspection system pattern recognition tool which compares die-to-die patterns and picks out visual anomalies. The KLA 2139 automatically generated defect map in FIG. 3B shows zero cracks on three wafers (no SACVD oxide layer cracking detected). Crack data for the controls shown in FIG. 3A evidence at least one SACVD oxide crack on almost every die on the wafer.

Disclosed embodiments can be used to form semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, Insulated Gate Bipolar Transistor (IGBT), CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A method of forming an integrated circuit (IC), comprising:
forming at least one hard mask layer on a device layer of a silicon-on-insulator (SOI) substrate including a handle portion and a buried oxide (BOX) layer between said device layer and said handle portion, said hard mask layer including a thermal silicon oxide layer directly on said device layer, a silicon nitride layer directly on said thermal silicon oxide layer, and a plasma-deposited silicon oxide layer directly on said silicon nitride layer;
etching using a pattern to form larger area trenches and smaller area trenches through said hard mask layer, said device layer and said BOX layer;
forming a dielectric liner for lining said larger area trenches and lining said smaller area trenches;
depositing a sub-atmospheric pressure chemical vapor deposition (SACVD) dielectric layer for filling said smaller area trenches and partially filling said larger area trenches;
bottom etching said larger area trenches through said SACVD dielectric layer to provide a top side contact to said handle portion;
densifying said SACVD dielectric layer after said bottom etching;
implanting said handle portion at a bottom of said larger area trenches to form a handle contact, and
filling said larger area trenches with an electrically conductive layer to form a top side ohmic contact to said handle contact.

2. The method of claim 1, wherein said electrically conductive layer comprises doped polysilicon, and said wherein filling comprises depositing in-situ doped polysilicon.

3. The method of claim 2, further comprising performing Chemical Mechanical Planarization (CMP) for removing overburden regions of said doped polysilicon stopping on said hard mask layer lateral to said larger area trenches and said smaller area trenches.

4. The method of claim 1, wherein said densifying said SACVD dielectric layer comprises furnace annealing at a temperature from 950° C. to 1050° C. in a non-oxidizing ambient for at least 20 minutes.

5. The method of claim 1, wherein an as-deposited thickness from said depositing said SACVD dielectric layer is at least 800 nm.

6. The method of claim 1, wherein said SACVD dielectric layer comprises silicon oxide and said depositing said SACVD dielectric layer comprises ozone-assisted SACVD using tetraethyl ortho-silicate (TEOS) as a silicon source.

7. The method of claim 1, wherein said smaller area trenches have an aspect ratio of between 3 and 15.

8. The method of claim 1, wherein said depositing said SACVD dielectric layer consists of a single-pass deposition.

9. The method of claim 1, wherein a trench depth for said larger area trenches and for said smaller area trenches ranges from 5 μm to 15 μm.

10. The method of claim 1, wherein said IC includes at least one drain extended metal-oxide-semiconductor (DEMOS) transistor.

11-19. canceled

20. A method of forming an integrated circuit (IC), comprising:
forming at least one hard mask layer on a device layer of a silicon-on-insulator (SOI) substrate including a handle portion and a buried oxide (BOX) layer between said device layer and said handle portion, said hard mask layer including a thermal silicon oxide layer directly on said device layer, a silicon nitride layer directly on said thermal silicon oxide layer, and a plasma-deposited silicon oxide layer directly on said silicon nitride layer;
etching using a pattern to form larger area top side contact (TSC) trenches and smaller area isolation trenches through said hard mask layer, said device layer and said BOX layer;
forming a dielectric liner for lining said larger area trenches and lining said smaller area isolation trenches;
depositing a sub-atmospheric pressure chemical vapor deposition (SACVD) dielectric layer for filling said smaller area isolation trenches and partially filling said larger area trenches;
bottom etching said larger area TSC trenches through said SACVD dielectric layer to provide a top side contact to said handle portion;
densifying said SACVD dielectric layer after said bottom etching;
implanting said handle portion at a bottom of said larger area TSC trenches to form a handle contact, and
filling said larger area TSC trenches with an electrically conductive layer to form a top side ohmic contact to said handle contact.

21. A method of forming an integrated circuit (IC), comprising:
forming a hard mask over a semiconductor layer, said hard mask layer including a thermal silicon oxide layer directly on said semiconductor layer, a silicon nitride layer directly on said thermal silicon oxide layer, and a plasma-deposited silicon oxide layer directly on said silicon nitride layer;
forming openings within said hard mask, said semiconductor layer and a buried oxide layer over a handle portion, said forming exposing said handle portion at bottoms of said openings;
depositing a dielectric layer into said openings, wherein said dielectric layer completely fills a narrower subset of said openings and partially fills a wider subset of said openings;
removing said dielectric layer from bottoms of said wider openings, thereby re-exposing said handle portion at bottoms of said wider openings;
densifying said dielectric layer after said re-exposing; and
filling said wider openings with an electrically conductive material to form a top side contact to said handle portion.

22. The method of claim 21, wherein said dielectric layer comprises a sub-atmospheric pressure chemical vapor deposition (SACVD) dielectric layer

23. The method of claim 21, wherein said openings comprise trenches.

24. The method of claim 21, further comprising implanting a dopant into said handle portion after said re-exposing, such that said electrically conductive material forms an ohmic connection to said handle portion.

25. The method of claim 21, further comprising forming a dielectric liner within said openings before depositing said dielectric layer.

26. The method of claim 21, wherein said narrower subset of openings have an aspect ratio of between 3 and 15.

27. The method of claim 21, wherein said openings have a trench depth within a range from 5 μm to 15 μm.

28. The method of claim 21, wherein said densifying said dielectric layer comprises furnace annealing at a temperature from 950° C. to 1050° C. in a non-oxidizing ambient for at least 20 minutes.

29. The method of claim 21, wherein an as-deposited thickness from said dielectric layer is at least 800 nm.
